(19) United States
(12) Patent Application Publication
(10) Pub. No.: US 2016/0294019 A1
(43) Pub. Date: Oct. 6, 2016

(54) BATTERY SYSTEM AND BATTERY CELL MANAGEMENT DEVICE

(71) Applicant: HITACHI, LTD., Tokyo (JP)

(72) Inventors: Shuko YAMAUCHI, Tokyo (JP); Takanori YAMAZOE, Tokyo (JP)

(73) Assignee: HITACHI, LTD., Tokyo (JP)

(21) Appl. No.: 15/037,231

(22) PCT Filed: Dec. 16, 2013
(86) PCT No.: PCT/JP2013/083607

§ 371 Date: May 17, 2016

(51) Int. Cl. H01M 10/42; G01R 31/36; H04Q 9/00; H01M 10/48

(52) U.S. Cl. CPC H01M 10/425; H01M 10/482; G01R 31/3606; G01R 31/3658; G01R 31/3679; H04Q 9/00; H01M 10/0525

(57) ABSTRACT

A battery system includes: a battery cell group composed of one or more battery cells; a battery cell management device that is provided corresponding to each battery cell group and acquires a measurement result concerning a charge state of each battery cell of the battery cell group; and a battery pack management device that performs radio communication with the battery cell management device. In the radio communication, a plurality of radio frequencies can be used.

### TECHNICAL FIELD

The present invention relates to a battery system and a battery cell management device.

### BACKGROUND ART

Now, under circumstances where global environment issues come to light, emission reduction of carbon dioxide is required for prevention of global warming. For example, gasoline engine cars, which are a major carbon dioxide emission source, have begun to be replaced by hybrid or pure electric cars. A large secondary battery system typically used as a power supply for the hybrid or pure electric cars is required to have high output and large capacity. Therefore, such a battery system generally includes a plurality of battery cells which are connected in series and in parallel.

A lithium-ion battery cell is widely known as a large capacity secondary battery. In handling the lithium-ion battery, some measures, such as prevention of high-voltage charge and prevention of performance degradation due to overdischarge, need to be taken. To this end, a large capacity battery system to be mounted in hybrid or pure electric cars, which is composed of lithium-ion battery cells, is generally provided with a function that monitors a battery state, such as a voltage, a current, or a temperature, for each battery cell to manage the state of each battery cell.

In the large capacity battery system, a plurality of battery cells are connected in multiple series and multiple parallel. Thus, when information management for the battery cell is performed by wired communication, the number of connecting man-hours at time of production is large, so that a wiring amount may become huge and, further, cost may increase due to miswiring caused due to increase in the number of wiring components and increase in the wiring amount. In addition, it is difficult to change a battery configuration after once connecting communication lines.

As an example of the above battery system, a power supply device disclosed in PTL 1 is known. This power supply device includes a plurality of battery modules connected in series and in parallel, each having a radio communication means. The radio communication means transmits by radio information concerning each battery module to a control module. As a result, a wiring between each battery module and control module can be omitted, thereby allowing a configuration of the power supply device to be changed readily.

### CITATION LIST

### Patent Literature

PTL 1: JP 2011-36106 A

### SUMMARY OF INVENTION

### Technical Problem

In recent years, the large capacity secondary battery system is used in various applications other than as the above-mentioned power supply for hybrid or pure electric cars. For example, in power generation by natural energy such as wind power generation or solar power generation, a power generation amount significantly varies depending on natural environment. Thus, to reduce adverse effect that the variation in the power generation amount has on a power system, generated power is temporarily stored in the large capacity secondary battery system. In addition to this, the battery system is used in various applications.

In view of the above situation, a versatile battery system that can be applied to various applications other than as the above-mentioned power supply for hybrid or pure electric cars is required. However, in the power supply device disclosed in PTL 1, the radio communication may be difficult to perform depending on an arrangement of each battery module, a positional relationship between each battery module and control module, a surrounding radio propagation environment, and the like. Further, a frequency that can be used in the radio communication may differ depending on the application. Thus, in the power supply device disclosed in PTL 1, although the number of battery modules may be changed readily, the application thereof is limited, resulting in poor versatility.

### Solution to Problem

A battery system according to the present invention includes: a battery cell group composed of one or more battery cells; a battery cell management device that is provided corresponding to each battery cell group and acquires a measurement result concerning a charge state of each battery cell of the battery cell group; and a battery pack management device that performs radio communication with the battery cell management device, wherein in the radio communication, a plurality of radio frequencies can be used.

A battery cell management device according to the present invention is one that is connected to a battery cell group composed of one or more battery cells and includes: a measurement circuit that measures a state of each battery cell of the battery cell group; a power supply circuit that generates a power supply voltage based on power supplied from the battery cells of the battery cell group; an antenna that receives a radio signal transmitted on one of a plurality of radio frequencies and transmitting a radio signal on one of the plurality of radio frequencies; and a radio communication section that modulates/demodulates the radio signal transmitted/received through the antenna.

Further, a rewritable storage area is provided in the battery cell management device.

### Advantageous Effects of Invention

According to the present invention, there can be realized a versatile battery system that can be applied to various applications.

### BRIEF DESCRIPTION OF DRAWINGS

FIG. 1 is a basic configuration view of a battery system according to an embodiment of the present invention.

FIG. 2 is a view illustrating a configuration of an electric-driven system including the battery system according to the embodiment of the present invention.

FIGS. 3(a) and 3(b) are explanatory views each illustrating a basic operation of the battery system according to the embodiment of the present invention.

FIG. 4 is a functional block diagram of a battery cell management device.

FIG. 5 is a view for explaining information to be transmitted from the battery cell management device on radio frequencies of 2.4 GHz band and 900 MHz band, respectively.

FIG. 6 is a view illustrating a configuration example of a modulation/demodulation circuit for first frequency band.

FIG. 7 is an explanatory view illustrating a radio transmission method from a battery pack management device to the battery cell management device.

FIG. 8 is an explanatory view illustrating a radio transmission method from the battery cell management device to battery pack management device.

### DESCRIPTION OF EMBODIMENTS

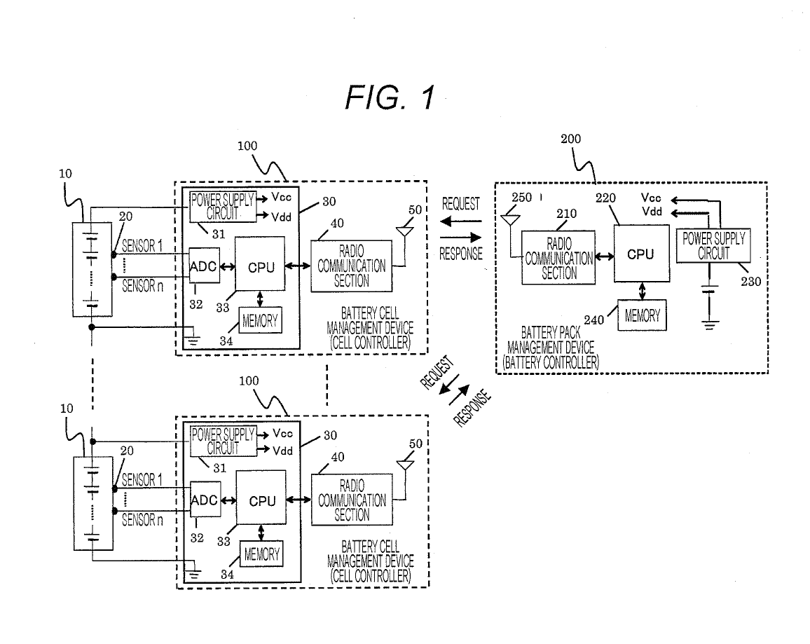

FIG. 1 is a basic configuration view of a battery system 1 according to an embodiment of the present invention.

In FIG. 1, a battery pack management device 200 performs radio communication with each battery cell management device 100. By this radio communication, the battery pack management device 200 can require each battery cell management device 100 to transmit thereto measurement information of each battery cell of a corresponding battery cell group 10, to execute cell balancing, and the like. In response to the request from the battery pack management device 200, each battery cell management device 100 transmits the measurement information of each battery cell of the corresponding battery cell group 10 to the battery pack management device 200 and executes the cell balancing.

Each battery cell management device 100 includes a plurality of sensors 20 provided corresponding to each battery cell of the corresponding battery cell group 10, a processing section 30, a radio communication section 40, and an antenna 50. The processing section 30 includes a power supply circuit 31, an AD converter 32, a CPU 33, and a memory 34. The memory 34 indicates a writable storage area for retaining logic or information, not a register memory to be used for CPU computation. For example, the memory 34 is a mask ROM or a rewritable EEPROM or flash memory. Each sensor 20 is a sensor for measuring a state of each battery cell of the battery cell group 10 and includes at least one of a voltage sensor, a current sensor, a temperature sensor, and a magnetic sensor. A measurement result concerning a state of the battery cell obtained by the sensor 20 is converted into a digital signal by the AD converter 32 and output to the CPU 33 as the measurement information. The above sensor 20 and AD converter 32 constitute a measurement circuit for measuring a state of each battery cell of the battery cell group 10.

The power supply circuit 31 receives power supplied from the battery cells of the battery cell group 10 and generates power supply voltages Vcc and Vdd based on the received power. The power supply voltage Vcc is used as an operating power supply for the AD converter 32 or CPU 33, and power supply voltage Vdd is used as an operating power supply for the radio communication section 40. The power supply circuit 31 can receive power from at least one of the plurality of battery cells constituting the battery cell group 10.

The CPU 33 executes processing for controlling operation of the battery cell management device 100. For example, the CPU 33 transmits the measurement information of each battery cell output from the AD converter 32 and stores the measurement information in the memory 34 in response to a request from the battery pack management device 200. Alternatively, in response to a request from the battery pack management device 200, the CPU 33 transmits by radio the measurement information stored in the memory 34 to the battery pack management device 200. Further alternatively, the CPU 33 receives or transmits information stored in the memory 34, such as flag information set upon occurrence of abnormality or individual cell information, to be written or read in response to a request from the battery cell management device. In the above transmission processing to the battery pack management device 200, the CPU 33 controls the radio communication section, 40 according to information to be transmitted to transmit the measurement information according to a state of each battery cell. Further, when a balancing request is transmitted from the battery pack management device 200, the CPU 33 controls a not illustrated balancing switch to execute balancing processing for equalizing a charge state of the battery cells of the battery cell group 10. The CPU 33 can execute various processing other than the above. The above functions of the CPU 33 may be realized by a logic circuit.

The radio communication section 40 is a circuit that executes processing or control for the battery cell management device 100 to perform radio communication with the battery pack management device 200. A radio signal transmitted from the battery pack management device 200 and received by the antenna 50 is demodulated by the radio communication section 40 and then output to the CPU 33. As a result, content of a request from the battery pack management device 200 is decoded by the CPU 33, and the CPU 33 executes processing according to the request content. Further, the radio communication section 40 uses the power supply voltage Vdd supplied from the power supply circuit 31 to modulate acquired measurement information with a predetermined frequency and outputs the modulated measurement information to the antenna 50. As a result, the measurement information according to a state of each battery cell of the battery cell group 10 is transmitted from the battery cell management device 100 to battery pack management device 200. A concrete configuration and operation of the radio communication section 40 will be described later in detail.

The battery pack management device 200 includes a radio communication section 210, a CPU 220, a power supply circuit 230, a memory 240, and an antenna 250. Like the power supply circuit 31 of the battery cell management device 100, the power supply circuit 230 generates power supply voltages Vcc and Vdd based on power supplied from a battery incorporated in the battery pack management device 200. The power supply circuit 230 may use externally supplied power; in this case, the battery for power supply to the power supply circuit 230 need not be incorporated in the battery pack management device 200.

The CPU 220 controls operation of the radio communication section 210 and memory 240. The radio communication section 210 operates under control of the CPU 220 and executes processing or control for the battery pack management device 200 to perform radio communication with the battery cell management device 100. The radio communication section 210 uses the power supply voltage Vdd supplied from the power supply circuit 230 to modulate a request of the measurement information to be transmitted to each battery cell management device 100 with a predetermined frequency and outputs the modulated measurement information request to the antenna 250. In response to the request, the measurement information according to a state of each battery cell of the battery cell group 10 is transmitted as a radio signal from each battery cell management device 100 to battery pack management device 200. The radio signal transmitted from each battery cell management device 100 and received by the antenna 250 is demodulated by the radio communication section 210 and then output to the CPU 220. As a result, the measurement information acquired by each battery cell management device 100 is decoded by the CPU 220, and the CPU 220 executes processing according to content of the measurement information as needed.

As described above, the battery pack management device 200 performs radio communication with each battery cell management device 100 to acquire the battery state detected by each battery cell management device 100. At this time, the battery pack management device 200 operates as a master that leads the communication, and each battery cell management device 100 operates as a slave that performs the communication based on an instruction form the master. Each battery cell management device 100 executes operation according to the request from the battery pack management device 200 and then transmits an acquired result to the battery pack management device 200 as needed.

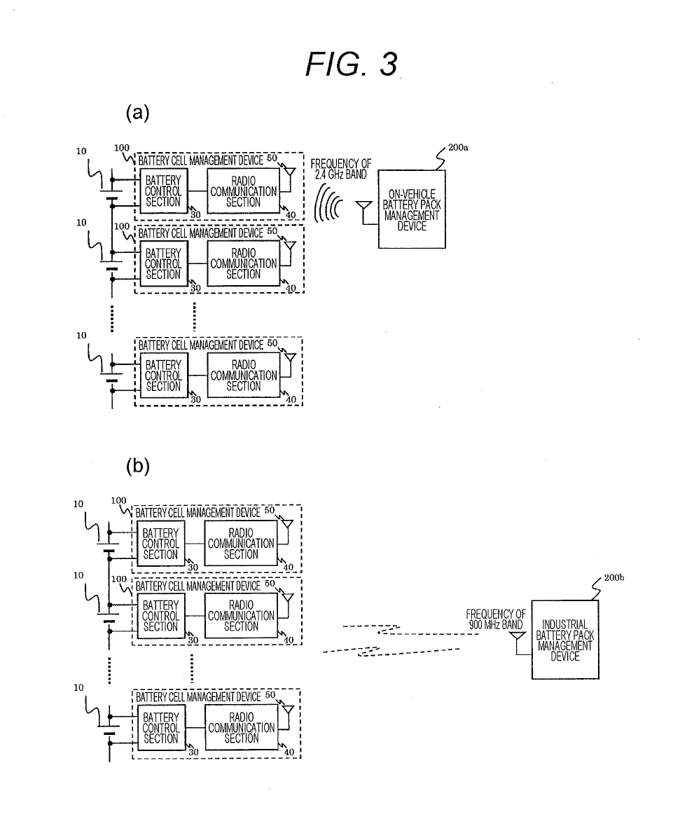

The radio communication between the battery pack management device 200 and each battery cell management device 100 may be performed using a plurality of frequencies. This point will be described later with reference to FIGS. 3(a) and 3(b).

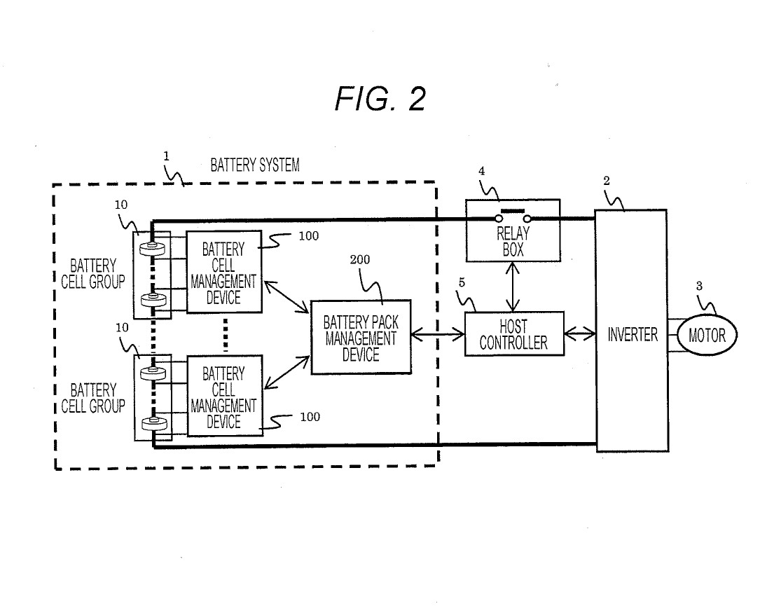

FIG. 2 is a view illustrating an example of a configuration of an electric-driven system including the battery system according to the embodiment of the present invention. In the example of FIG. 2, the battery system 1 having the above configuration is applied to an on-vehicle electric-driven system. The electric-driven system includes the battery system 1, an inverter 2, a motor 3, a relay box 4, and a host controller 5.

The battery system 1 includes one or more battery cell groups 10 each composed of one or more battery cells and further includes the battery cell management device 100 for each battery cell group 10. Each battery cell management device 100 performs measurement to acquire information required to detect a charge state (SOC: State of Charge) and a degradation state (SOH: State of Health) of the battery cell group 10 and performs measurement (a voltage, a current, a temperature, etc.) concerning detection of abnormality. Then, each battery cell management device 100 uses the power supplied from the battery cells of the battery cell group 10 to perform radio communication with the battery pack management device 200 to thereby transmit a measurement result or necessary information concerning the charge state or degradation state of the battery cell group 10 and abnormality monitoring or information requested from the battery pack management device to the battery pack management device 200. Details of the communication performed at this time will be described later.

The battery pack management device 200 acquires, from each battery cell management device 100, the measurement result concerning the charge state or degradation state of the battery cell group 10 of the corresponding battery cell management device 100. Then, based on the acquired measurement result, the battery pack management device 200 estimates the charge state or degradation state of each battery cell group 10 and transmits a result of the estimation to the host controller 5.

The host controller 5 controls the inverter 2 and relay box 4 based on the estimation result of the charge state or degradation state of battery cell group 10 transmitted from the battery pack management device 200. The inverter 2 converts DC power supplied from each battery cell group 10 when the relay box 4 is in a conductive state into three-phase AC power and supplies the three-phase AC power to the motor 3. As a result, the motor 3 is driven into rotation to generate a drive force. When the motor 3 is made to perform regenerative operation, three-phase regenerative power generated by the motor 3 is converted into DC power. Then, the converted DC power is output to each battery cell group 10 to charge the battery cells of each battery cell group 10. Such operation of the inverter 2 is controlled by the host controller 5.

The battery system 1 can be used in various applications other than for the electric-driven system as illustrated in FIG. 2. For example, the battery system 1 can be used commonly in an on-vehicle system that is mounted on a vehicle such as a hybrid or pure electric car and makes the vehicle travel by the drive force of the motor 3 and in an industrial system that is installed in a factory or the like and makes an industrial machine work by the drive force of the motor 3. Other than the above, the battery system 1 can be applied to various electric-driven systems that use the drive force of the motor 3. That is, the battery system 1 is a versatile system that can be used in various applications and can have a configuration according to the application.

FIGS. 3(a) and 3(b) are explanatory views each illustrating a basic operation of the battery system 1 according to the embodiment of the present invention. In FIGS. 3(a) and 3(b), one battery cell is illustrated as a representative of the plurality of battery cells of the battery cell group 10 connected with each battery cell management device 100.

In FIGS. 3(a) and 3(b), the battery pack management device 200 of FIGS. 1 and 2 is illustrated as an on-vehicle battery pack management device 200a (FIG. 3(a)) and an industrial battery pack management device 200b (FIG. 3(b)). The on-vehicle battery pack management device 200a represents the battery pack management device 200 when the battery system 1 is applied to an on-vehicle system, and the industrial battery pack management device 200b represents the battery pack management device 200 when the battery system 1 is applied to an industrial system.

In FIG. 3(a), the on-vehicle battery pack management device 200a performs radio communication with each battery cell management device 100 using a radio frequency of 2.4 GHz band. The 2.4 GHz band is a frequency band used in industrial/scientific/medical instruments in Japan and other countries and is widely used for a wireless LAN and the like. Generally, the 2.4 GHz radio frequency band enables high-speed and high-reliable communication in a short range of about 2 m or less.

In FIG. 3(b), the industrial battery pack management device 200b performs radio communication with each battery cell management device 100 using a radio frequency of 900 MHz band. The 900 MHz band is a frequency band used in a radio tag (RFID) in Japan and other countries. Generally, the 900 MHz radio frequency band enables a comparatively long-range communication. With this radio frequency band, communication is enabled even when a radio wave shielding substance exists.

In a combination with the on-vehicle battery pack management device 200a or industrial battery pack management device 200b, even if a frequency on which a radio signal is transmitted is changed, each battery cell management device 100 can use the same frequency as that on which the radio signal has been transmitted to transmit a radio signal to the on-vehicle battery pack management device 200a or industrial battery pack management device 200b. With this configuration, the battery system 1 can change a radio frequency used in the radio communication between the battery pack management device 200 (on-vehicle battery pack management device 200a or industrial battery pack management device 200b) and each battery cell management device 100 depending on a communication distance between the battery pack management device 200 and battery cell management device 100 or application of the battery system 1.

The on-vehicle battery pack management device 200a and industrial battery pack management device 200b illustrated in FIGS. 3(a) and 3(b), respectively, as examples of the battery pack management device 200 and the frequency band used in the radio communication with the on-vehicle battery pack management device 200a or industrial battery pack management device 200b are just illustrative. For example, the battery pack management device 200 illustrated in FIG. 3(b) as the industrial battery pack management device 200b may be configured to check a battery state during storage in a warehouse or at time of stock management conducted before assembly, irrespective of the application (e.g., for an on-vehicle system, an industry storage device, or the like) of the battery system. That is, the battery system 1 may be used in applications other than for the industrial system and may perform radio communication using a different frequency from those described above. The battery system 1 may have any configuration as long as a plurality of radio frequencies can be used in the radio communication between the battery pack management device 200 and each battery cell management device 100.

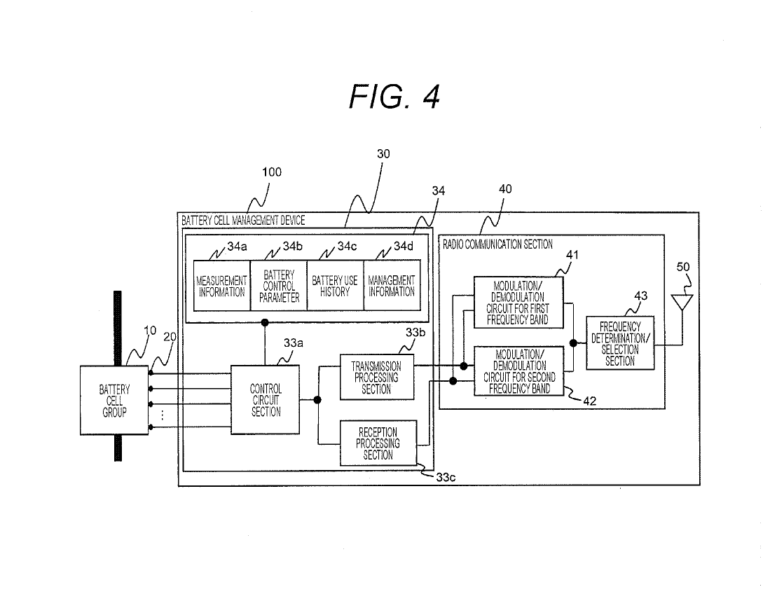

FIG. 4 is an example of a functional block diagram of the battery cell management device 100. As illustrated in FIG. 4, the battery cell management device 100 includes, in the processing section 30, functional blocks of a control circuit section 33a, a transmission processing section 33b, and a reception processing section 33c. The memory 34 stores measurement information 34a, a battery control parameter 34b, a battery use history 34c, and a management information 34d. The radio communication section 40 includes a modulation/demodulation circuit 41 for first frequency band, a modulation/demodulation circuit 42 for second frequency band, and a frequency determination/selection section 43.

Here, information stored in the memory 34 will be described. The measurement information 34a is measurement information from the sensor 20, which indicates a measurement result of a state of each battery cell of the battery cell group 10 connected with the battery cell management device 100. When each battery cell is charged/discharged in the battery system 1, the state measurement result of each battery cell is always transmitted from the battery cell management device 100 to battery pack management device 200 and is sequentially recorded, as needed, in the memory 34 as measurement information 34a by the control circuit section 33a. The battery control parameter 34b is parameter information used in control of each battery cell and includes, for example, an internal resistance value, a SOC-OCV curve, various calculation constants, initial values of these parameters, and the like. The content of the battery control parameter 34b is read, based on a request transmitted from the battery pack management device 200, only before start of the battery state calculation of the battery pack management device 200. When maintenance or the like is required, the content of the battery control parameter 34b is updated as needed. The battery use history 34c is information concerning a use state of each battery cell and includes, for example, at least one of the following information: an energizing time, a deterioration degree of capacity; a cumulative use capacity; a maximum/minimum voltage; an average used voltage; a presence/absence of abnormality flag; and the like. The content of the battery use history 34c is updated appropriately when the battery cell management device 100 is put into a sleep state in response to a stop request from the battery pack management device 200. The management information 34d is information for use in managing each battery cell and includes, for example, a production history, a management number, a production number, a specification, and the like. The content of the management information 34d is previously determined and is not updated normally.

The control circuit section 33a corresponds to a part in charge of processing operations of the AD converter 32 and CPU 33 of FIG. 1 and acquires, according to a request from the reception processing section 33c, sensing information of each battery cell of the cell group 10, such as a voltage, a current, and a temperature, measured by the above-mentioned sensor 20. The acquired information is sequentially transmitted to the radio communication section 40 by the transmission processing section 33b and is then transmitted from the radio communication section 40 to the battery pack management device 200 on a first or second frequency according to the radio frequency from the battery pack management device 200. Further, according to a request from the battery pack management device 200, the acquired information is recorded in the memory 34 as the measurement information 34a. Further, the control circuit section 33a performs, in response to a balancing request transmitted from the battery pack management device 200, balancing processing for each battery cell of the cell group 10 or performs, in response to a transmission request from the battery pack management device 200, processing of reading out various information recorded in the memory 34 and transmitting them outside through the transmission processing section 33b and radio communication section 40.

The transmission processing section 33b is a function realized by the CPU 33 of FIG. 1 and generates, in response to a request from the battery pack management device 200, transmission information in a predetermined format based on information from the control circuit section 33a. The transmission information generated by the transmission processing section 33b is output to the radio communication section 40.

The reception processing section 33c is a function realized by the CPU 33 of FIG. 1. The reception processing section 33c receives reception information output from the radio communication section 40 that has received a radio signal from the battery pack management device 200 and records a variety of information included in the reception information in the memory 34 through the control circuit section 33a. With this operation, the contents of the battery control parameter 34b and the like stored in the memory 34 are updated. When information indicating various requests that the battery pack management device 200 issues to the battery cell management device 100, such as the balancing request and transmission request of various information, is included in the reception information, the control circuit section 33a executes processing according to the content of the information.

In the radio communication section 40, the modulation/demodulation circuit 41 for first frequency band and modulation/demodulation circuit 42 for second frequency band correspond, respectively, to specific radio frequencies used in the radio communication between the battery cell management device 100 and battery pack management device 200. For example, the modulation/demodulation circuit 41 for first frequency band corresponds to the radio frequency of the above-mentioned 2.4 GHz band, and modulation/demodulation circuit 42 for second frequency band corresponds to the radio frequency of the above-mentioned 900 MHz band. The frequency determination/selection section 43 selects one of the modulation/demodulation circuit 41 for first frequency band and modulation/demodulation circuit 42 for second frequency band according to the frequency of the radio signal transmitted from the battery pack management device 200.

The following describes an example of a communication operation of the battery cell management device 100 with reference to FIG. 4. The battery pack management device 200 of FIG. 1 is powered-ON, and the CPU 220 thereof is activated. Then, the battery pack management device 200 transmits, to the battery cell management device 100, a radio signal including a transmission request of information recorded in the memory 34. The radio signal is received by the antenna 50 of the battery cell management device 100 and is then input to the radio communication section 40.

In the radio communication section 40, the frequency determination/selection section 43 identifies the frequency of the radio signal received from the battery pack management device 200 and selects one of the modulation/demodulation circuit 41 for first frequency band and modulation/demodulation circuit 42 for second frequency band. While a description will be made assuming that the modulation/demodulation circuit 41 for first frequency band is selected, it can also be applied when the modulation/demodulation circuit 42 for second frequency band is selected.

The modulation/demodulation circuit 41 for first frequency band demodulates the radio signal transmitted from the radio communication section 40 and received by the antenna 50 to thereby acquire reception information from the radio signal and then outputs the acquired reception information to the reception processing section 33c.

When the battery system 1 is in a non-operation mode, the control circuit section 33a, transmission processing section 33b, and reception processing section 33c are put into a sleep state so as to minimize a dark current for suppression of a power consumption of each battery cell. When the radio signal from the battery pack management device 200 is received by the radio communication section 40, the sleep state is canceled. The reception processing section 33c decodes the reception information acquired by the modulation/demodulation circuit 41 for first frequency band and outputs an on-activation command to the control circuit section 33a and transmission processing section 33b.

The control circuit section 33a measures a state of each battery cell of the battery cell group 10 upon activation in response to the command from the reception processing section 33c. The measurement value is output as it is from the control circuit section 33a to the transmission processing section 33b and is stored as needed in the memory 34 as the measurement information 34a. The transmission processing section 33b generates transmission information based on the information from the control circuit section 33a and outputs the generated transmission information to the radio communication section 40.

The transmission information output from the transmission processing section 33b is input to the modulation/demodulation circuit 41 for first frequency band in the radio communication section 40. The modulation/demodulation circuit 41 for first frequency band modulates the input transmission information to generate a radio signal and transmits the generated radio signal to the battery pack management device 200 through the antenna 50. At this time, the modulation/demodulation circuit 41 for first frequency band changes, at a predetermined timing, impedance with respect to a non-modulated carrier wave transmitted from the battery pack management device 200 according to the transmission information to thereby transmit the transmission information as a reflection wave of the non-modulated carrier wave. This point will be described later more in detail.

The battery pack management device 200 receives the radio signal thus transmitted from the battery cell management device 100 to confirm activation of the battery cell management device 100. Thereafter, the battery pack management device 200 repeatedly transmits, to the battery cell management device 100, the radio signal including the transmission request of the measurement information at a regular interval (e.g., at a period ranging from 10 ms to 60 s) and receives the measurement information transmitted correspondingly from the battery management device 100. On the other hand, the battery cell management device 100 receives the radio signal transmitted at a regular interval from the battery pack management device 200 and performs correspondingly measurement of a state of each battery cell of the battery cell group 10 at a regular interval. Then, the battery cell management device 100 transmits a radio signal including the measurement information based on the measurement result to the battery pack management device 200.

When the battery system 1 needs to be stopped, the battery pack management device 200 transmits a radio signal including an operation stop request to the battery cell management device 100. Upon receiving the radio signal, the battery cell management device 100 updates the content of the battery use history 34c recorded in the memory 34 and puts the control circuit section 33a, transmission processing section 33b, and reception processing section 33c into a sleep state. Thus, operations of respective sections of the battery cell management device 100 are stopped, excluding the minimum configuration required to be active in a standby state.

With the above-described communication operation, information concerning each battery cell of the battery cell group 10 can be individually checked in the battery pack management device 200. Therefore, even when an abnormality occurs or degradation progresses in any battery cell, the battery cell in question can be easily identified and replaced with a new one. That is, in the above case, the battery cell group 10 needs to be replaced with a new one in a conventional configuration; however, application of the present invention allows replacement in units of battery cells. This can reduce maintenance cost. Further, even when different types of battery cells are mixed, it is possible to avoid control failure caused due to parameter mismatch by setting an adequate control parameter in each battery cell.

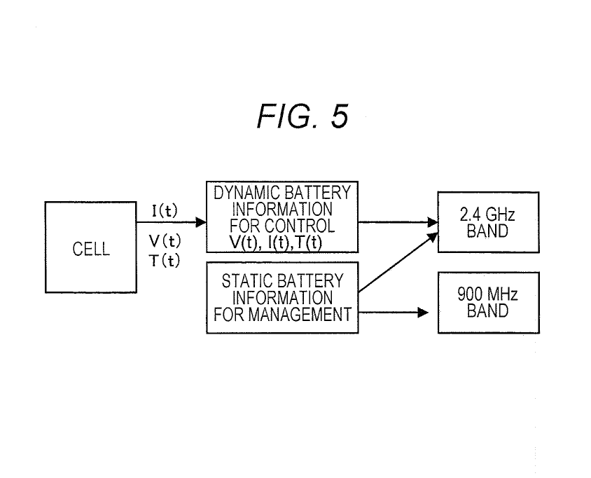

Here, a type of the transmission information from the battery cell management device 100 will be described. As described above, the battery cell management device 100 can use a plurality of radio frequencies in the radio communication with the battery pack management device 200. Thus, by transmitting different information on different frequencies, adequate information can be transmitted according to the application of the battery system 1. This point will be described below with reference to FIG. 5.

FIG. 5 is a view for explaining information to be transmitted from the battery cell management device 100 on the radio frequencies of 2.4 GHz band and 900 MHz band, respectively. As illustrated in FIG. 5, in the radio communication using the radio frequency of 2.4 GHz band, the battery cell management device 100 transmits dynamic battery information for control acquired from each battery cell and previously stored static battery information for management to the battery pack management device 200. On the other hand, in the radio communication using the radio frequency of 900 MHz band, the battery cell management device 100 transmits the previously stored static battery information for management to the battery pack management device 200.

The dynamic battery information for control is, e.g., the measurement information 34a illustrated in FIG. 4 and includes information such as a voltage V(t), a current I(t), a temperature T(t), and the like of each battery cell of the battery cell group 10 at time (t). The battery pack management device 200 uses the above dynamic battery information for control so as to control a state of each battery cell. On the other hand, the static battery information for management includes, e.g., the battery control parameter 34b, battery use history 34c, management information 34d, and the like illustrated in FIG. 4. The battery pack management device 200 uses the above static battery information for management so as to manage each battery cell.

When the battery system 1 is applied to an on-vehicle system as described in FIG. 3(a), the radio communication using the radio frequency of 2.4 GHz band is performed between the on-vehicle battery pack management device 200a and battery cell management device 100. In a state where the battery system 1 is stored in a warehouse before being incorporated in another system or where the battery system 1 is undergoing maintenance, the radio communication may be performed using the radio frequency of 900 MHz band. With this configuration, the battery pack management device 200 can read, from the battery cell management device 100, information required for storing or maintaining a large number of battery cells by using the radio frequency of 900 MHz band that can provide comparatively long range radio communication at low cost. Thus, when the battery system 1 is combined with the on-vehicle battery pack management device 200 of FIG. 2, the battery pack management device 200 and the battery cell management device 100 integrated with the battery cells of the battery cell group 10 are mounted in a vehicle, so that the communication distance is within 2 m. The cars are exported to a plurality of countries and often travel from one country to another, so that, during traveling, the 2.4 GHz band radio communication that can be used commonly throughout the world is used to perform communication of both the dynamic battery information for control and static battery information for control/management. On the other hand, during storage in a warehouse or maintenance, the 900 MHz band radio communication that can read information at low cost is used to read the static battery information for control/management of each battery cell. The static battery information for control/management refers to fixed information that is internally stored so as to be able to be read while the battery is not activated, typified by information for identifying the individual battery cell, such as battery information, a LOT name, a production date, a history, and an ID, a rated capacity (Ah), a rated voltage (V), a SOC-OCV, a DCR, a resistance value, a battery control parameter, a use history log, and an abnormality flag. On the other hand, the dynamic battery information for control refers to information obtained by sensing a state of each battery cell and is varied from time to time. Thus, even when a read frequency or reply frequency upon communication is changed due to a state of the battery system, information can be acquired properly.

When the battery system 1 is applied to an industrial system as described in FIG. 3(b), the radio communication using the radio frequency of 900 MHz band may be performed between the industrial battery pack management device 200b and battery cell management device 100. Alternatively, when a communication distance is comparatively long, or when a sufficient communication speed is ensured, the radio communication using the radio frequency of 900 MHz band may be performed.

When the dynamic battery information for control or static battery information for management is transmitted by radio, it may be encrypted so as to prevent data from being stolen or falsified by a malicious third person. Such a measure is effective especially when the static battery information for management is transmitted by radio over a long range during storage of the battery system 1 in a warehouse.

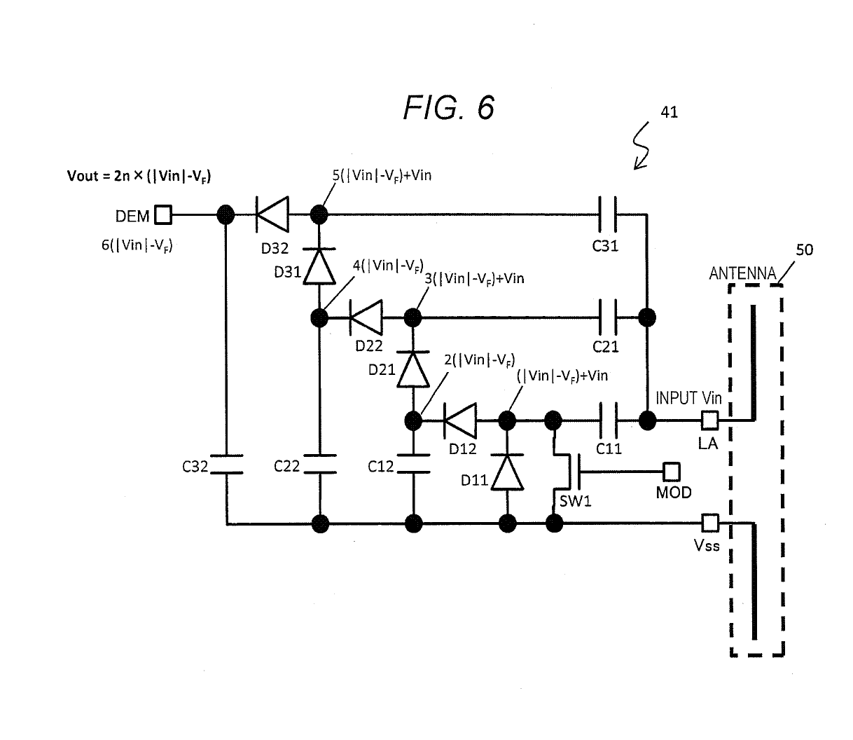

The following describes configurations of the modulation/demodulation circuit 41 for first frequency band and modulation/demodulation circuit 42 for second frequency band illustrated in FIG. 4. FIG. 6 is a view illustrating a configuration example of the modulation/demodulation circuit 41 for first frequency band. The modulation/demodulation circuit 41 for first frequency band and modulation/demodulation circuit 42 for second frequency band have the same configuration, so only the configuration of the modulation/demodulation circuit 41 for first frequency band is illustrated in FIG. 6.

As illustrated in FIG. 6, the modulation/demodulation circuit 41 for first frequency band includes diodes D11, D12 and capacitors C11, C12 that constitute a first stage charge pump circuit, diodes D21, D22 and capacitors C21, C22 that constitute a second stage charge pump circuit, and diodes D31, D32 and capacitors C31, C32 that constitute a third stage charge pump circuit. That is, the modulation/demodulation circuit 41 for first frequency band illustrated in FIG. 6 is configured as a three-stage charge pump circuit. Further, the modulation/demodulation circuit 41 for first frequency band includes terminals LA and Vss connected to the antenna 50, a switch SW1 for modulating a transmission signal, an input terminal MOD of a modulated signal for controlling operation of the switch SW1, and an output terminal DEM of a demodulated signal.

The modulation/demodulation circuit 42 for second frequency band has the same configuration as that of FIG. 6; however, capacitance values of the capacitors C11 to C32 are set according to the radio signal frequency that the modulation/demodulation circuit 41 for first frequency band and modulation/demodulation circuit 42 for second frequency band use, respectively. That is, the capacitance values of the capacitors C11 to C32 differ between the modulation/demodulation circuit 41 for first frequency band and modulation/demodulation circuit 42 for second frequency band.

At time of reception of a radio signal transmitted from the battery pack management device 200, when the antenna 50 receives the radio signal, an input voltage Vᵢₙ according to an amplitude of the input radio signal is input to the terminals LA and Vss. As illustrated in FIG. 6, the input voltage Vᵢₙ is amplified by the first- to third-stage charge pump circuits. As a result, an output voltage Vₒᵤₜ represented by the following expression (1) is output to the output terminal DEM. In the expression (1), V_{F} represents a forward drop voltage of the diodes D11 to D32.

Vₒᵤₜ=6(|Vᵢₙ|−V_{F}) (1)

When the above expression (1) can be generalized as the following expression (2):

Vₒᵤₜ=2n×(|Vᵢₙ|−V_{F}) (2)

where n is the number of stages of the charge pump circuit.

It is assumed here that the battery pack management device 200 transmits a radio signal of an ASK-modulated wave in which an amplitude of a carrier wave is changed according to a value of data in the transmission information. In this case, the battery cell management device 100 that has received the radio signal from the battery pack management device 200 can demodulate the received radio signal by measuring a change in the output voltage Vₒᵤₜ represented by the above expressions (1) and (2).

On the other hand, at time of transmission of a radio signal to the battery pack management device 200, a modulated signal according to a value of data included in the transmission information is input to the input terminal MOD at a predetermined communication rate. Then, the switch SW1 repeats ON and OFF in response to the input modulated signal to change impedance of the antenna 50 with respect to the non-modulated carrier wave transmitted from the battery pack management device 200 according to the content of the transmission information, thereby allowing modulation of a radio signal to be transmitted.

By adopting the above-described configuration, the modulation/demodulation circuit 41 for first frequency band and modulation/demodulation circuit 42 for second frequency band can be realized with a simple configuration without a need for an oscillator.

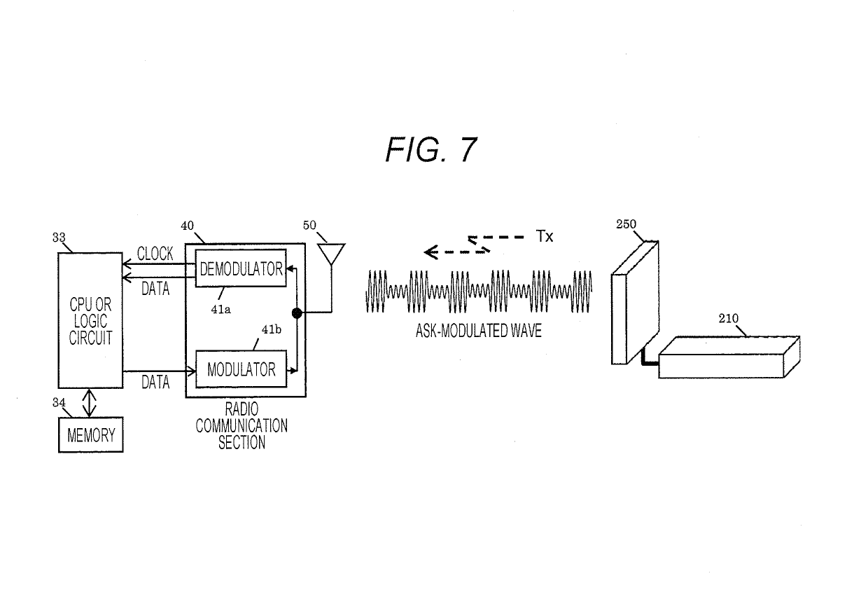

The following further describes the radio communication performed between the battery cell management device 100 and battery pack management device 200. FIG. 7 is an explanatory view illustrating a radio transmission method from the battery pack management device 200 to battery cell management device 100.

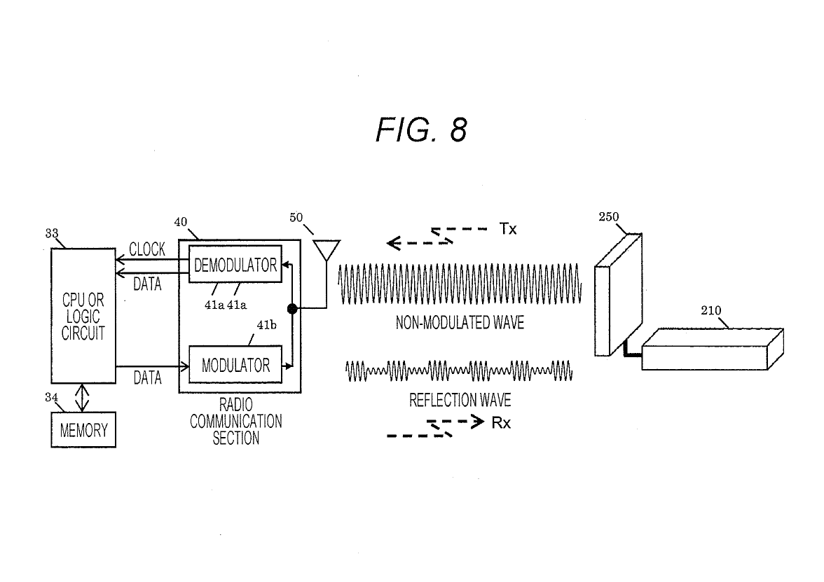

As illustrated in FIG. 7, at time of radio transmission from the battery pack management device 200 to the battery cell management device 100, the battery pack management device 200 transmits the ASK-modulated wave in which an amplitude of a carrier wave frequency is changed according to the transmission data from the radio communication section 210 to the battery cell management device 100 through the antenna 250. The ASK-modulated wave is received by the antenna 50 of the battery cell management device 100 and is then demodulated by a demodulator 41a provided in the radio communication section 40. In FIGS. 7 and 8, a part (charge pump circuits of FIG. 6) that performs demodulation of the radio signal in the modulation/demodulation circuit 41 for first frequency band of FIG. 4 is illustrated as the demodulator 41a. The demodulator 41a demodulates the received ASK-modulated wave to reproduce a clock and data and outputs them to the CPU 33 as reception data. The reception data is stored in the memory 34 by the CPU 33 and is read out as needed.

Although the ASK-modulated wave is used in FIG. 7, another modulation system may be used. For example, a PSK-modulated wave in which a phase of a carrier wave frequency is changed according to the transmission data or a modulation system combining the ASK-modulated wave and PSK-modulated wave may be used.

FIG. 8 is an explanatory view illustrating a radio transmission method from the battery cell management device 100 to battery pack management device 200.

As illustrated in FIG. 8, at time of radio communication from the battery cell management device 100 to the battery pack management device 200, the battery pack management device 200 successively transmits a non-modulated carrier wave from the radio communication section 210 through the antenna 250. On the other hand, the battery cell management device 100 uses a modulator 41b provided in the radio communication section 40 to change, at a predetermined communication rate, the impedance of the antenna 50 according to the transmission data. In FIGS. 7 and 8, a part (switch SW1 of FIG. 6) that performs modulation of the radio signal in the modulation/demodulation circuit 41 for first frequency band of FIG. 4 is illustrated as the modulator 41b. That is, by switching the switch SW1 between when the transmission data bit is “1” and when it is “0”, a connection state between a pair of antenna elements constituting the antenna 50 is controlled to change the impedance thereof. At this time, as an operating power supply for the switch SW1, the above-mentioned power supply voltage Vdd generated by the power supply circuit 31 based on power supplied from the battery cells of the corresponding battery cell group 10 is used.

When the battery cell management device 100 receives, while changing the impedance of the antenna 50, the non-modulated carrier wave transmitted from the battery pack management device 200, a reflection wave according to a state of the impedance at that time is transmitted from the antenna 50. That is, when the non-modulated carrier wave from the battery pack management device 200 is received in an impedance-matched state, the non-modulated carrier wave is completely absorbed in the antenna 50, with the result that no reflection wave is transmitted therefrom. On the other hand, when the non-modulated carrier wave from the battery pack management device 200 is received in an impedance-unmatched state, a part of the non-modulated carrier wave is transmitted from the antenna 50 as the reflection wave. Thus changing the reflection wave with respect to the non-modulated carrier wave from the battery pack management device 200 according to the transmission data enables the radio communication from the battery cell management device 100 to battery pack management device 200. Further, the radio communication from the battery cell management device 100 to battery pack management device 200 is performed by utilizing the reflection wave with respect to the non-modulated carrier wave transmitted from the battery pack management device 200, so that, in the battery cell management device 100, a power consumption required for the radio communication can be reduced.

According to the embodiment of the present invention described above, the following effects can be obtained.

(1) The battery system 1 includes a battery cell group 10 composed of one or more battery cells, a battery cell management device 100 that is provided corresponding to each battery cell group 10 and acquires a measurement result concerning a charge state of each battery cell of the battery cell group 10, and a battery pack management device 200 that performs radio communication with the battery cell management device 100. In the thus configured battery system 1, a plurality of radio frequencies can be used in the radio communication between the battery pack management device 200 and battery cell management device 100. With this configuration, there can be realized the versatile battery system 1 that can be applied to various applications.

(2) The battery cell management device 100 includes a radio communication section 40. The radio communication section 40 receives a radio signal transmitted from the battery pack management device 200 on one of the plurality of radio frequencies and transmits a radio signal to the battery pack management device 200 on one of the plurality of radio frequencies. With this configuration, there can be realized the battery cell management device 100 that can a plurality of frequencies in the radio communication with the battery pack management device 200.

(3) The battery pack management device 200 successively transmits a non-modulated carrier wave to the battery cell management device 100 on one of the plurality of radio frequencies. The battery cell management device 100 uses the radio communication section 40 to change impedance with respect to the non-modulated carrier wave transmitted from the battery pack management device 200 at a predetermined timing according to a measurement result of a state of each battery cell of the battery cell group 10 to thereby transmit by radio the measurement result of a state of each battery cell of the battery cell group 10 to the battery pack management device 200 using on one of the plurality of radio frequencies. With this configuration, a power consumption at time of transmission can be reduced in the battery cell management device 100.

(4) The battery cell management device 100 includes a sensor 20 and an AD converter 32 that constitute a measurement circuit for measuring a state of each battery cell of the battery cell group 10 and an antenna 50 for receiving the non-modulated carrier wave transmitted from the battery pack management device 200. The radio communication section 40 changes impedance of the antenna 50 according to a state of each battery cell of the battery cell group 10 measured by the measurement circuit. With this configuration, the battery cell management device 100 can reliably measure a state of each battery cell of the corresponding battery cell group 10 and transmit a result of the measurement to the battery pack management device 200.

(5) The battery cell management device 100 transmits, to the battery pack management device 200, information different for each radio frequency used in the radio, communication. Specifically, in the radio communication, the battery cell management device 100 can use a first radio frequency (e.g., 2.4 GHz band) and a second radio frequency (e.g., 900 MHz). The battery cell management device 100 uses the first radio frequency to transmit, to the battery pack management device 200, first transmission information including dynamic information for controlling a state of each battery cell of the battery cell group 10 and uses the second radio frequency to transmit, to the battery pack management device 200, second transmission information including static information for managing each battery cell of the battery cell group 10. With this configuration, it is possible to transmit optimum information according to application of the battery system 1 from the battery cell management device 100 to battery pack management device 200.

(6) The battery cell management device 100 includes a sensor 20 and an AD converter 32 that constitute a measurement circuit for measuring a state of each battery cell of the battery cell group 10, a power supply circuit 31 that generates a power supply voltage based on power supplied from the battery cells of the battery cell group 10, an antenna 50 for receiving a radio signal transmitted from the battery pack management device 200 on one of the plurality of radio frequencies and transmitting a radio signal to the battery pack management device 200 on one of the plurality of radio frequencies, and a radio communication section for modulating/demodulating the radio signal transmitted/received through the antenna 50. With this configuration, there can be realized the battery cell management device 100 that can use a plurality of radio frequencies in the radio communication with the battery pack management device 200.

(7) The battery pack management device 200 changes a radio frequency to be used in the radio communication depending on at least one of a communication distance from the battery cell management device 100 and application of the battery system 1. With this configuration, there can be realized the battery pack management device 200 that performs radio communication with the battery cell management device 100 using an optimum radio frequency according to a situation.

Further, the battery system 1 has a plurality of frequency bands that can be used commonly throughout the world among frequency bands regulated for each country, whereby a low cost battery system can be realized.

The above embodiment and various modifications are illustrative, and the present invention is not limited thereto unless the features of the invention are impaired.

### REFERENCE SIGNS LIST

1 battery system

10 battery cell group

20 sensor

30 processing section

31 power supply circuit

32 AD converter

33 CPU

34 memory

40 radio communication section

41 modulation/demodulation circuit for first frequency band

42 modulation/demodulation circuit for second frequency band

43 frequency determination/selection section

50 antenna

100 battery cell management device

200 battery pack management device

210 radio communication section

220 CPU

230 power supply circuit

240 memory

250 antenna

1. A battery system comprising:
a battery cell group composed of one or more battery cells;
a battery cell management device that is provided corresponding to each battery cell group and acquires a measurement result concerning a charge state of each battery cell of the battery cell group; and
a battery pack management device that performs radio communication with the battery cell management device, wherein
in the radio communication, a plurality of radio frequencies including a first radio frequency and a second radio frequency can be used, and
the battery cell management device uses the first radio frequency to transmit, to the battery pack management device, first transmission information including dynamic information for controlling a state of each battery cell of the battery cell group and uses the second radio frequency to transmit, to the battery pack management device, second transmission information including static information for managing each battery cell of the battery cell group.

2. A battery system comprising:
a battery cell group composed of one or more battery cells;
a battery cell management device that is provided corresponding to each battery cell group and acquires a measurement result concerning a charge state of each battery cell of the battery cell group; and
a battery pack management device that performs radio communication with the battery cell management device, wherein
in the radio communication, a plurality of radio frequencies can be used, and
the battery pack management device changes a radio frequency to be used in the radio communication depending on at least one of a communication distance from the battery cell management device and application of the battery system.

3. The battery system according to claim 1, wherein
the battery cell management device includes a radio communication section that receives a radio signal transmitted from the battery pack management device on one of the plurality of radio frequencies and transmits a radio signal to the battery pack management device on one of the plurality of radio frequencies,
the battery pack management device successively transmits a non-modulated carrier wave to the battery cell management device on one of the plurality of radio frequencies,
the battery cell management device uses the radio communication section to change impedance with respect to the non-modulated carrier wave transmitted from the battery pack management device at a predetermined timing according to a measurement result of a state of each battery cell of the battery cell group to transmit by radio the measurement result of a state of each battery cell of the battery cell group to the battery pack management device using on one of the plurality of radio frequencies.

4. The battery system according to claim 3, wherein
the battery cell management device includes a measurement circuit that measures a state of each battery cell of the battery cell group and an antenna that receives the non-modulated carrier wave transmitted from the battery pack management device, and
the radio communication section changes impedance of the antenna according to a state of each battery cell of the battery cell group measured by the measurement circuit.

5. The battery system according to claim 1, wherein
the battery cell management device transmits, to the battery pack management device, information different for each radio frequency used in the radio communication.

6. (canceled)

7. The battery system according to claim 1, wherein
the battery cell management device includes:
a measurement circuit that measures a state of each battery cell of the battery cell group;
a power supply circuit that generates a power supply voltage based on power supplied from the battery cells of the battery cell group;
an antenna that receives a radio signal transmitted from the battery pack management device on one of the plurality of radio frequencies and transmitting a radio signal to the battery pack management device on one of the plurality of radio frequencies; and
a radio communication section that modulates/demodulates the radio signal transmitted/received through the antenna.

8. (canceled)

9. (canceled)

10. The battery system according to claim 1, wherein the first radio frequency is a radio frequency of 2.4 GHz band, and
the second radio frequency is a radio frequency of 900 MHz band.

11. The battery system according to claim 2, wherein
the plurality of radio frequencies include at least one of a radio frequency of 2.4 GHz band and a radio frequency of 900 MHz band.
